(19) United States
(12) Patent Application Publication
(10) Pub. No.: US 2015/0069596 A1
(43) Pub. Date: Mar. 12, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Kazushige KAWASAKI, Kanagawa-ken (JP); Yoichiro KURITA, Tokyo (JP); Satoshi TSUKIYAMA, Kanagawa-ken (JP); Masayuki MIURA, Mie-ken (JP)

(73) Assignee: KABUSHIKI KAISHA TOSHIBA, Tokyo (JP)

(21) Appl. No.: 14/190,921

(22) Filed: Feb. 26, 2014

(30) Foreign Application Priority Data
Sep. 12, 2013 (JP) 2013-189846

(51) Int. Cl. H01L 23/367; H01L 21/48

(52) U.S. Cl. CPC H01L 23/367; H01L 21/4817
USPC 257/712; 438/122

(57) ABSTRACT

According to one embodiment, a semiconductor device includes a metal plate, a plurality of semiconductor chips, an insulation layer, a wiring layer, external connection terminals and a sealing resin portion. The metal plate includes a first surface and the plurality of semiconductor chips are laminated on a second surface of the metal plate. The insulation layer and the wiring layer are provided on the semiconductor chips. The external connection terminals are provided on the insulation layer and the wiring layer. The sealing resin portion seals the plurality of semiconductor chips while exposing the first surface of the metal plate. At least one pair of opposing outer peripheral surfaces of the metal plate are covered with the sealing resin portion.

### CROSS-REFERENCE TO RELATED APPLICATION

This application is based upon and claims the benefit of priority from Japanese Patent Application No. 2013-189846, filed Sep. 12, 2013, the entire contents of which are incorporated herein by reference.

### FIELD

Embodiments described herein relate generally to a semiconductor device and a method of manufacturing the same.

### BACKGROUND

There exists a semiconductor device having a plurality of semiconductor chips laminated (stacked) onto each other, and the semiconductor chips are sealed by an overlying molded resin portion to form a packaged device. As an example, a semiconductor device having a plurality of semiconductor chips laminated on a metal plate has been used, and the semiconductor chips are sealed by an overlying molded resin portion together with the metal plate. The metal plate enhances transfer of heat produced by the device and also strengthens the packaged semiconductor device.

In order to enhance the thermal properties of the semiconductor device, a portion of the metal plate is exposed, i.e., is uncovered by the molded resin portion. When the metal plate is exposed, there is a possibility that the metal plate may be separated (peeled-off) from the device, which detrimentally impacts the reliability of the semiconductor device.

### DESCRIPTION OF THE DRAWINGS

FIG. 1 is a plan view of a semiconductor device according to a first embodiment.

FIG. 2 is a cross-sectional view along line A-A shown in FIG. 1.

FIG. 3 is a cross-sectional view along line B-B shown in FIG. 1.

FIG. 4 is a flowchart for explaining the process of manufacturing the semiconductor device shown in FIG. 1.

FIGS. 5-13 are schematic views showing the steps in the process of manufacturing the semiconductor device shown in FIG. 1.

FIG. 14 is a plan view of a semiconductor device according to a second embodiment.

FIG. 15 is a cross-sectional view along line C-C shown in FIG. 14.

FIG. 16 is a cross-sectional view along line D-D shown in FIG. 14.

FIG. 17 is a cross-sectional view for explaining a dicing line in the manufacture of the semiconductor device shown in FIG. 14.

FIG. 18 is a cross-sectional view of a semiconductor device according to a third embodiment.

FIG. 19 is a flowchart for explaining process of manufacturing the semiconductor device shown in FIG. 18.

FIGS. 20-21 are schematic views showing the steps in the process of manufacturing the semiconductor device shown in FIG. 18.

### DETAILED DESCRIPTION

According to embodiments, there is provided a semiconductor device having an exposed metal plate that resists separation from the device.

In general, according to one embodiment, a semiconductor device includes: a metal plate; a plurality of semiconductor chips; an insulation layer; a wiring layer; external connection terminals and a sealing resin portion. The metal plate includes a first surface having a quadrangular shape. The plurality of semiconductor chips are laminated on a second surface of the metal plate opposite to the first surface. The insulation layer and the wiring layer are provided on a side of the semiconductor chips opposite to the position of the metal plate with respect to the semiconductor chips. The external connection terminals are provided on a side semiconductor chips opposed to the insulation layer and the wiring layer. The sealing resin portion seals the plurality of semiconductor chips while exposing the first surface of the metal plate. Among outer peripheral surfaces which are continuously formed with outer peripheries of the first surface of the metal plate, at least one pair of opposite outer peripheral surfaces are covered with the sealing resin portion.

A semiconductor device and a method of manufacturing the semiconductor device according to embodiments are explained in detail with reference to attached drawings hereinafter. The present disclosure is, however, not limited to these embodiments.

### First Embodiment

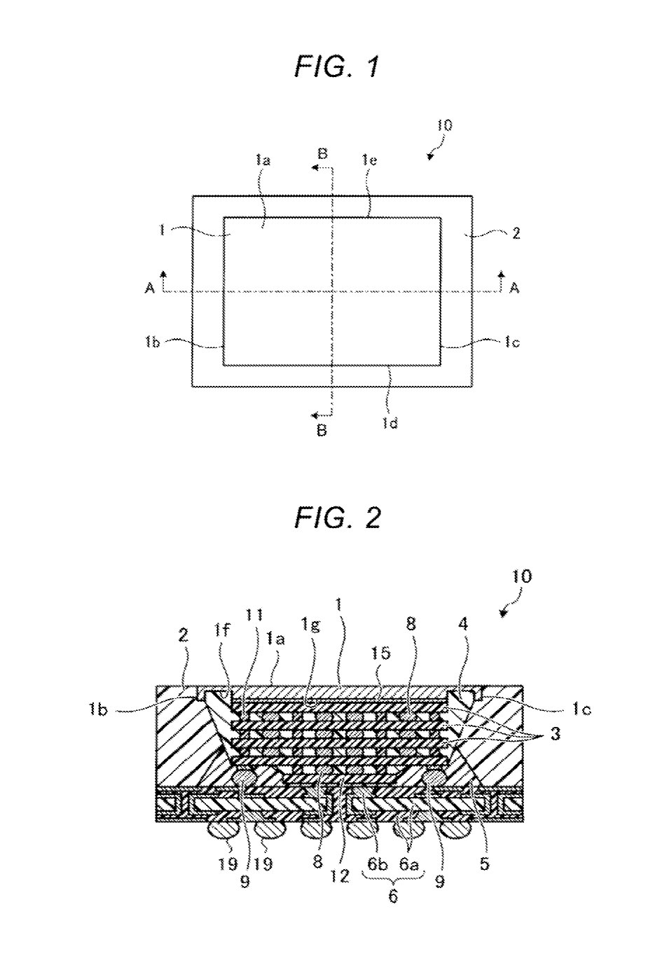

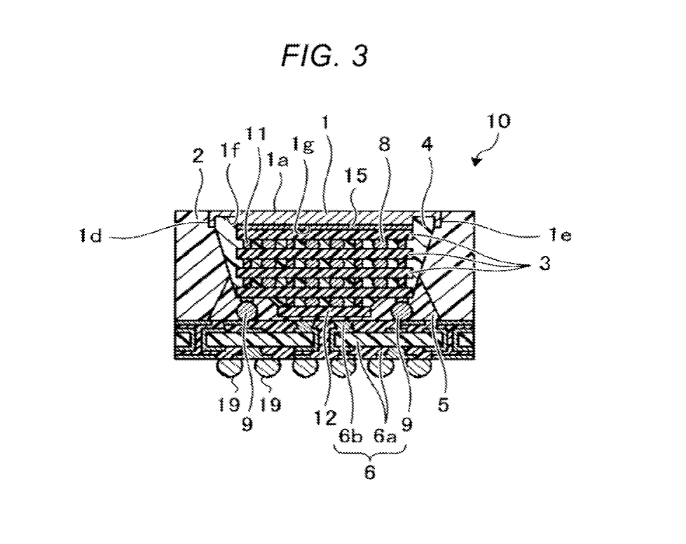

FIG. 1 is a plan view of a semiconductor device 10 according to a first embodiment. FIG. 2 is a cross-sectional view as viewed in the direction indicated by an arrow taken along line A-A shown in FIG. 1. FIG. 3 is a cross-sectional view as viewed in the direction indicated by an arrow taken along line B-B shown in FIG. 1. The semiconductor device 10 includes: a metal plate 1; semiconductor memories (semiconductor memory chips) 3; a logic LSI (semiconductor logic chip) 12; a circuit board (supporting printed circuit board) 6; and a resin mold portion 2.

The metal plate 1 is a plate member formed using metal such as aluminum or a nickel alloy sold as Alloy 42. The metal plate 1 has a first major surface 1a having a rectangular shape. The plurality of semiconductor memories 3 are chips which are laminated on a second major surface 1g which is a surface of the metal plate 1 on a side opposite to the first major surface 1a. The semiconductor memories 3 comprise a memory element, such as an NAND flash memory, for example.

The semiconductor memory 3 which is directly laminated on the metal plate 1 is adhered to the second major surface 1g using an adhesive layer 15. The semiconductor memories 3 which are laminated to each other are adhered to each other by an adhesive resin 11 disposed between each of the semiconductor memories 3. The semiconductor memories 3 are electrically connected with each other by bumps 8 comprising, for example, solder.

A logic LSI 12 is laminated on the semiconductor memory 3 positioned farthest from the metal plate 1. The logic LSI 12 and the semiconductor memories 3 are electrically connected with each other by the bumps 8. The logic LSI 12 is a control element which controls writing and reading of information to and from the semiconductor memories 3, and comprises a NAND controller or an NAND I/F control LSI, for example.

A first underfill resin 4 is provided in gaps formed between the semiconductor memories 3 and a gap formed between the semiconductor memory 3 and the logic LSI 12. The metal plate 1, the semiconductor memories 3 and the logic LSI 12 are more firmly fixed to each other by the first underfill resin 4 in the gaps. A groove if is formed on the second major surface 1g of the metal plate 1. The groove if is formed near a periphery of the metal plate 1 such that the groove if surrounds the laminated semiconductor memories 3. The groove if is provided to confine the first underfill resin 4 and prevent discharge of the first underfill resin 4 from the second major surface 1g of the metal plate 1 when the gaps are filled with the first underfill resin 4. In the explanation made hereinafter, a structural body where the semiconductor memories 3 and the logic LSI 12 are laminated on the metal plate 1 is also referred to as a first laminated body.

The circuit board 6 includes an insulation layer 6a made of a resin and a wiring layer 6b made of metal. The insulation layer 6a has a core layer and a build-up layer. The first laminated body is mounted on the circuit board 6 in a position where the semiconductor chip (the logic LSI 12 in this embodiment) is mounted on an uppermost layer of the circuit board 6 such that the first laminated body is opposing the circuit board 6. Bumps 9 are arranged between the circuit board 6 and the semiconductor memory 3 which is positioned farthest from the metal plate 1. The wiring layer 6b, which is formed on the circuit board 6, and the semiconductor memory 3 are electrically connected with each other by the bumps 9. A gap formed between the first laminated body and the circuit board 6 is filled with a second underfill resin 5. The first laminated body and the circuit board 6 are more firmly fixed to each other by the second underfill resin 5 in the gap. In the explanation made hereinafter, a structural body where the first laminated body is mounted on the circuit board 6 is also referred to as a second laminated body.

Bumps 19 which constitute external connection terminals are formed on a surface of the circuit board 6 which is a surface opposite to a surface on which the first laminated body is mounted. The bumps 19 are electrically connected with the wiring layer 6b of the circuit board 6. Accordingly, the bumps 19 are electrically connected with the semiconductor memory 3 by the wiring layer 6b and the bumps 9.

The surface of the circuit board 6 on which the first laminated body is mounted and the periphery of the first laminated body are sealed by the molded resin portion 2 made of a resin. The first surface 1a of the metal plate 1 is exposed, i.e., not covered by, the molded resin portion 2. All outer peripheral surfaces 1b to 1e which are continuously formed on the outer periphery of the first surface 1a of the metal plate 1 are covered by the molded resin portion 2. A cuboid portion, i.e., a box shape having generally flat sides having a cuboid shape is formed such that the cuboid portion includes the metal plate 1, the molded resin portion 2 and the circuit board 6. The bumps 19 which constitute the external connection terminals are formed on one surface of the cuboid portion. In the explanation made hereinafter, the first underfill resin 4, the second underfill resin 5 and the resin mold portion 2 are also collectively referred to as a sealing resin portion.

The first underfill resin 4, the second underfill resin 5 and the resin mold portion 2 contain silica filler for the purpose of adjusting coefficients of linear expansion thereof, or the like. The contents (percentage) of silica filler in the first underfill resin 4 and the second underfill resin 5 are set less than the percentage of silica filler in the molded resin portion 2 so that the first underfill resin 4 and the second underfill resin 5 exhibit greater fluidity (less viscosity) than the molded resin portion 2. Accordingly, the first underfill resin 4 and the second underfill resin 5 can be easily and smoothly filled in the gap formed between the semiconductor memories 3 and the gap formed between the first laminated body and the circuit board 6.

According to the above-mentioned semiconductor device 10, the first major surface 1a of the metal plate 1 is exposed from (uncovered by) the resin mold portion 2. Accordingly, a thickness of the semiconductor device may be decreased compared to a semiconductor device where the first major surface 1a is covered with the resin mold portion. Further, the first major surface 1a of the metal plate 1 is exposed from the resin mold portion 2 and hence, heat generated by the semiconductor memories 3 and the logic LSI 12 may be easily radiated from the device and through the metal plate 1.

All outer peripheral surfaces 1b to 1e which are continuously formed about the outer periphery of the first major surface 1a of the metal plate 1 are covered by the molded resin portion 2 and hence, the metal plate 1 can be more firmly fixed by the resin mold portion 2. If the outer peripheral surfaces 1b to 1e were not covered with the resin mold portion 2 according to the embodiment, a force applied directly to the outer peripheral surfaces 1b to 1e of the metal plate 1 could cause the metal plate 1 to separate (peel off) from the first laminated body. In this embodiment, however, all outer peripheral surfaces 1b to 1e are covered with the molded resin portion 2 and the surface of the molded resin portion 2 is coplanar with the first major surface 1a of the metal plate 1. Thus, a force which acts to peel off the metal plate 1 is difficult to apply to the outer peripheral surfaces 1b to 1e. Due to such a constitution, the reliability of the semiconductor device 10 may be ensured.

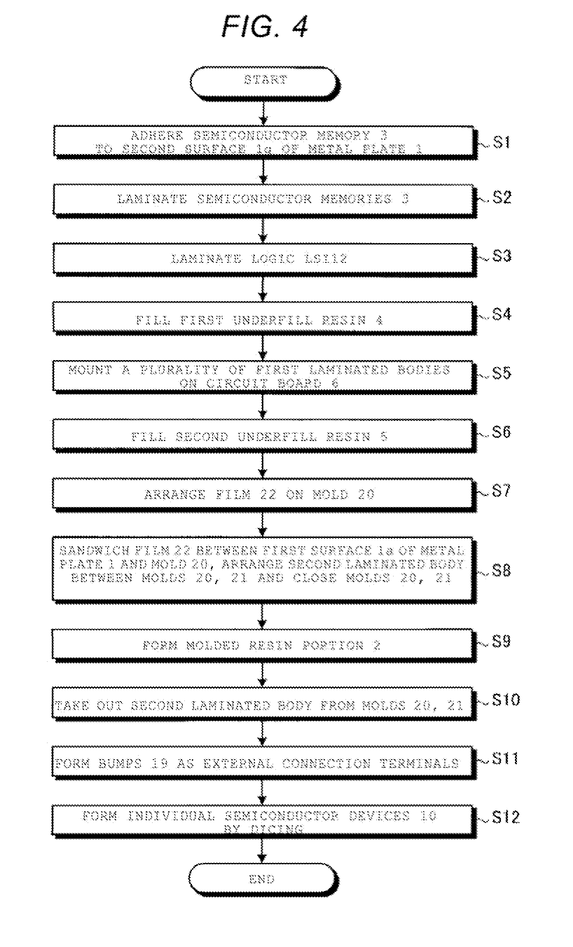

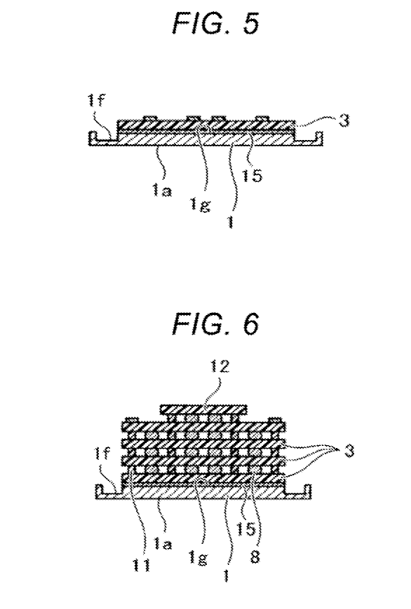

Next, a method of manufacturing the semiconductor device 10 is explained. FIG. 4 is a flowchart for explaining the process of manufacturing the semiconductor device 10 shown in FIGS. 1-3. FIG. 5 to FIG. 13 are views showing respective processing steps in the method of manufacturing the semiconductor device 10 shown in FIGS. 1-3.

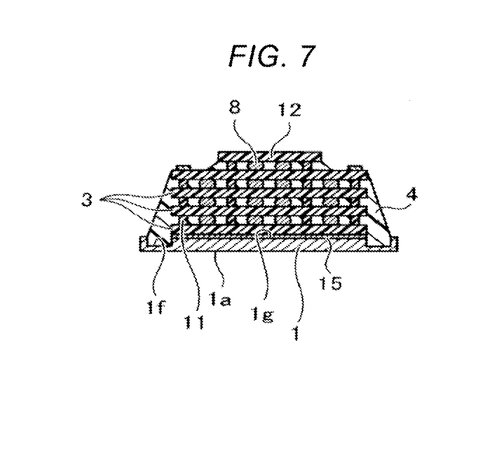

The semiconductor memory 3 is adhered to the second major surface 1g of the metal plate 1 using an adhesive layer 15 (see step S1 and FIG. 5). Next, additional semiconductor memories 3 are laminated on the semiconductor memory 3 adhered to the second surface 1g (see step S2 and FIG. 6). In laminating the multiple semiconductor memories 3, the semiconductor memories 3 are electrically connected with each other using the bumps 8. Then, the logic LSI 12 is laminated on the semiconductor memory 3 which is positioned farthest from the metal plate 1 (see step S3 and FIG. 6). In laminating the logic LSI 12, the logic LSI 12 and the semiconductor memory 3 are electrically connected with each other using the bumps 8. Next, the first underfill resin 4 is filled in the gap formed between the semiconductor memories 3 and the gap formed between the semiconductor memory 3 and the logic LSI 12 (see step S4 and FIG. 7). The first laminated body is formed by the processes described above.

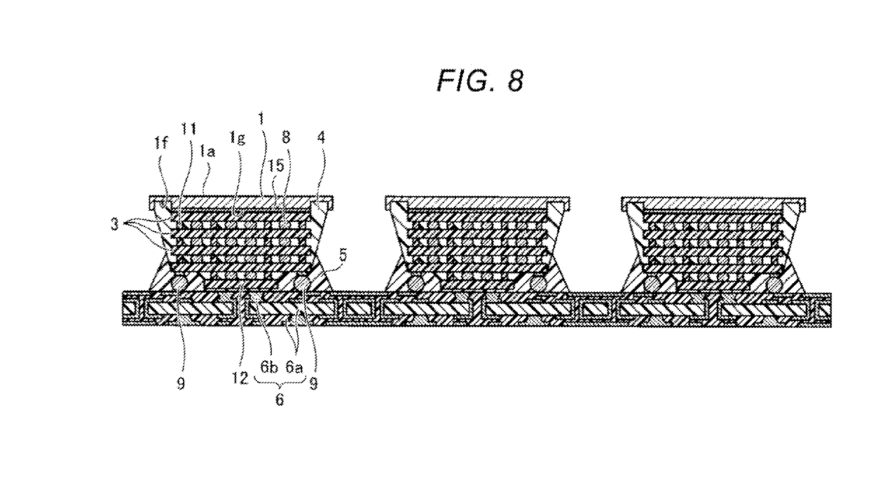

Next, a plurality of first laminated bodies are mounted on the circuit board 6 in a state where the logic LSIs 12, which are semiconductor chips laminated on uppermost layers of the circuit boards 6, oppose the circuit board 6 (see step S5 and FIG. 8). In mounting the first laminated bodies on the circuit boards 6, the first laminated bodies and the circuit boards 6 are electrically connected with each other using the bumps 9. Next, the second underfill resin 5 is filled in the gaps formed between the first laminated bodies and the circuit boards 6 (see step S6 and FIG. 8). The second laminated bodies are formed by the processes described above.

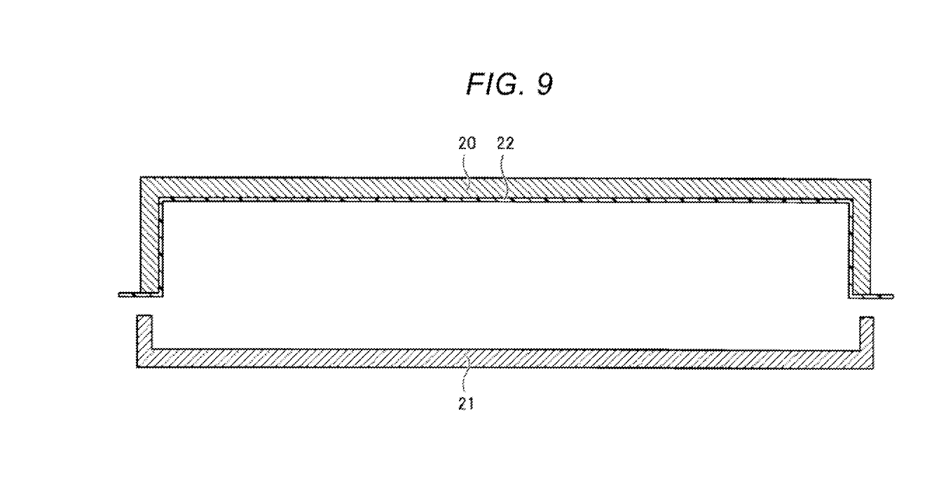

Next, molds 20 and 21 are used for forming the molded resin portion 2. A film 22 is provided on a surface of the mold 20 which faces the first major surfaces 1a of the metal plates 1 (see step S7 and FIG. 9). The film 22 is a mold release film which is used for easing the removal of the semiconductor device 10 from the molds 20, 21, for example.

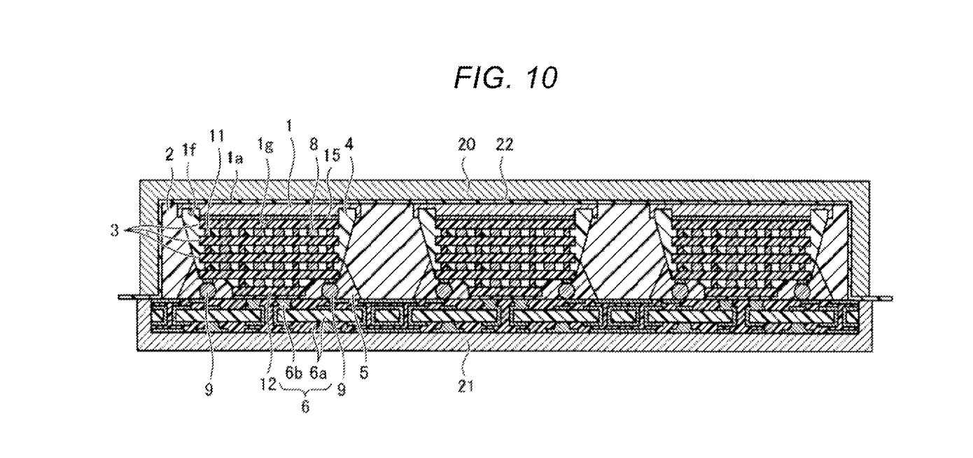

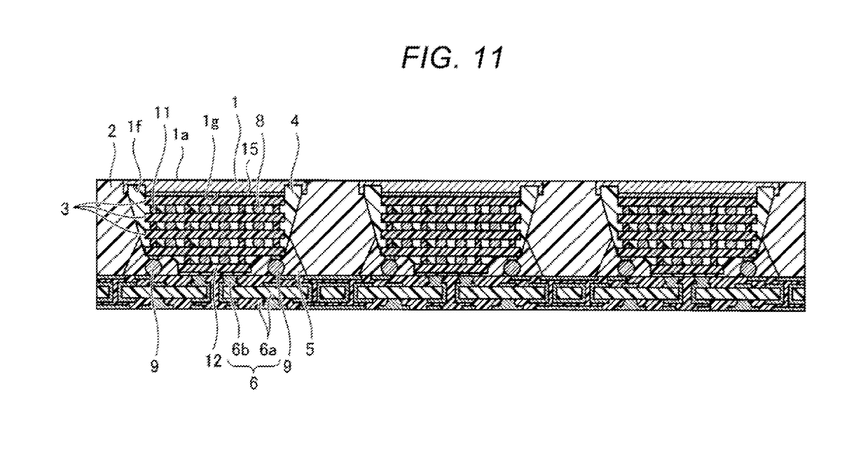

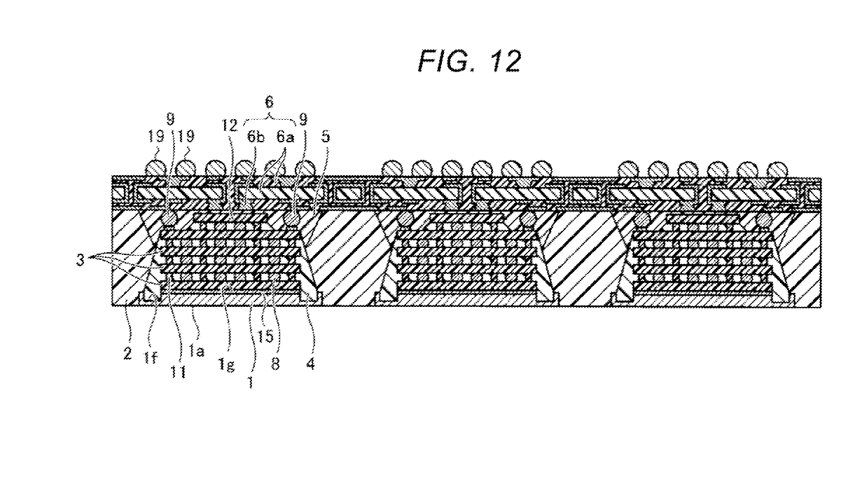

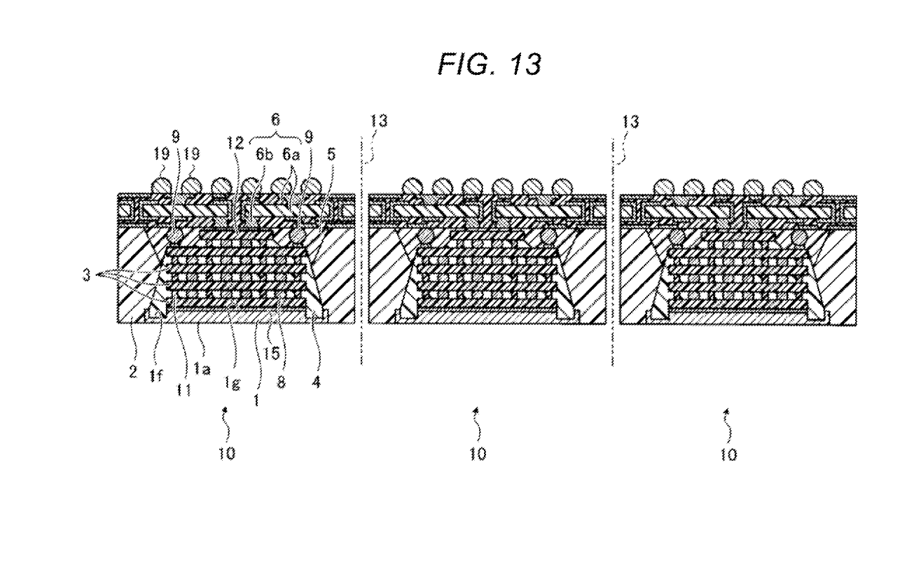

Next, the second laminated bodies are arranged between the molds 20, 21 in a state where the film 22 is sandwiched between the molds 20, 21 and the first major surfaces 1a of the metal plates 1, and the molds 20, 21 are closed (see step S8 and FIG. 10). Next, the molded resin portion 2 is formed by filling a resin in the inside of the molds 20, 21 (see step S9 and FIG. 10). Then, the molds 20, 21 are removed and the molded resin portion 2 remains on the second laminated bodies (see step S10 and FIG. 11). The bumps 19 which constitute the external connection terminals are then formed (see step S11 and FIG. 12). Then, dicing is used to separate the laminated bodies thus manufacturing individual semiconductor devices 10 (see step S12 and FIG. 13). The semiconductor devices 10 are manufactured by the processes described above. In the above-mentioned processes, although the detailed explanation of the step of forming the bumps 8, 9 and the step of forming the adhesive resin 11 is omitted, these portions may be formed at appropriate times, such as at the time of manufacturing the semiconductor memories 3, or before the lamination step.

In this embodiment, because the area of the metal plate is less than the area of the upper surface of the cuboid shaped package, all outer peripheral surfaces 1b to 1e of the metal plate 1 are covered by the molded resin portion 2 and hence, in performing dicing in step S12, dicing lines 13 are set parallel to, and spaced outwardly from, the outer peripheral sides of the metal plate 1 (normal to the first major surface 1a of the metal plate 1) and pass outside the region of the metal plate 1.

According to the above-mentioned processes of manufacturing the semiconductor device 10, the release film 22 is sandwiched between the first major surface 1a of the metal plate 1 and the mold 20 and hence, molding resin does not flow onto the first major surface 1a thereby ensuring exposure of the first major surface 1a from the molded resin portion 2.

Further, there may be a possibility where a gap is formed between the mold 20 and the first major surface 1a due to an error in manufacturing of the second laminated bodies, manufacturing of the molds 20, 21, or the like. When the gap is formed between the mold 20 and the first major surface 1a, there exists a possibility that resin intrudes between the mold 20 and the first major surface 1a in step S9 so that the first surface 1a is covered with the molded resin portion 2. However, in this embodiment, the film 22 sandwiched between the mold 20 and the first major surface 1a is configured to resiliently deform and hence, irregularities in distance between the mold 20 and the first major surface 1a can be absorbed by the film 22. Accordingly, by covering the first surface 1a of the metal plate 1 with the film 22, the intrusion of the resin between the mold 20 and the first surface 1a can be prevented. Due to such a constitution, it is possible to enhance a yield of the semiconductor devices 10 manufactured by the above-mentioned manufacturing processes.

### Second Embodiment

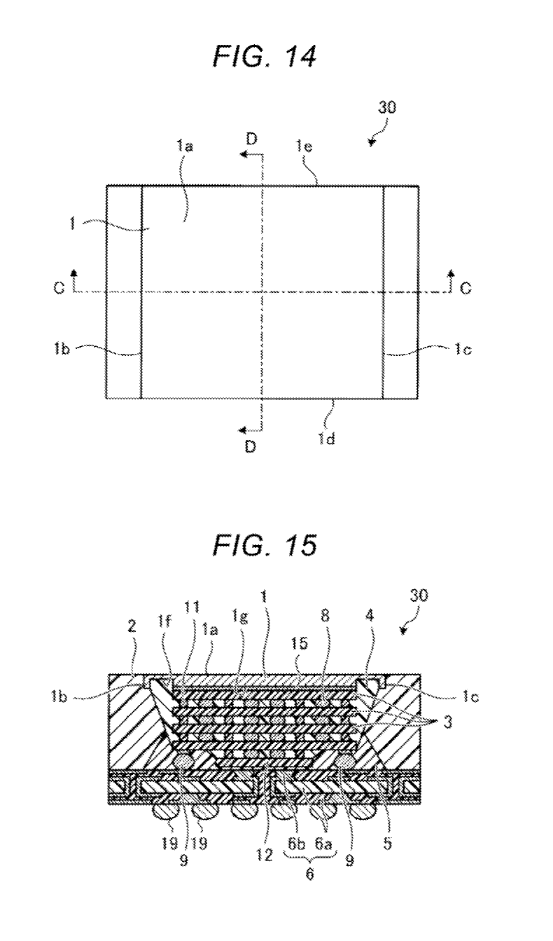

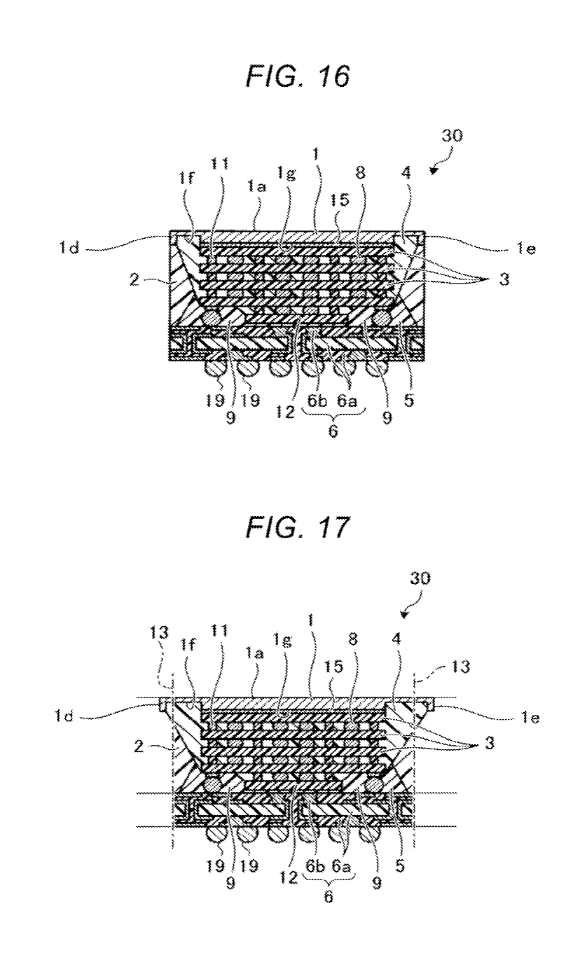

Next, a semiconductor device 30 according to a second embodiment is explained. FIG. 14 is a plan view of the semiconductor device 30 according to the second embodiment. FIG. 15 is a cross-sectional view as viewed in the direction indicated by an arrow taken along line C-C shown in FIG. 14. FIG. 16 is a cross-sectional view as viewed in the direction indicated by an arrow taken along line D-D shown in FIG. 14. FIG. 17 is a cross-sectional view showing dicing lines in manufacturing the semiconductor device 30 shown in FIG. 14. In this embodiment, the same reference numerals used in the first embodiment are used for the elements of the second embodiment and the detailed explanation of these parts is omitted for brevity.

In this embodiment, out of the four outer peripheral surfaces 1b to 1e which are continuously formed about outer peripheral sides of the metal plate 1, one pair of opposing outer peripheral surfaces 1b, 1c are covered with the molded resin portion 2, and the other pair of opposing outer peripheral surfaces 1d, 1e are exposed from, i.e., uncovered by, the molded resin portion 2.

By covering one pair of opposing outer peripheral surfaces 1b, 1c with the molded resin portion 2, the metal plate 1 is difficult to separate and, at the same time, by exposing the other pair of opposing outer peripheral surfaces 1d, 1e from the molded resin portion 2, the molded resin portion 2 can be smaller. In other words, the semiconductor device 30 can be miniaturized as viewed in a plan view, as compared to that shown in FIG. 1, if the areas of the first major surfaces 1a of the metal plates 1 are the same.

Particularly, in this embodiment, among the outer peripheral sides of the first major surface 1a of the metal plate 1, the outer peripheral surfaces 1b, 1c, which are formed as short sides, are covered with the resin mold portion 2, and the outer peripheral surfaces 1d, 1e which are formed as long sides are exposed from the molded resin portion 2. If the same force is applied to one of the long sides 1d, 1e versus one of the short sides 1b, 1c of the first major surface 1a, that force is more likely to cause peeling if applied to a short side 1b, 1c. Accordingly, in this embodiment, the outer peripheral surfaces 1b, 1c, which are the short sides, are covered with and protected by the resin mold portion 2. In the same manner as the above-mentioned embodiment, the first surface 1a of the metal plate 1 is exposed from the resin mold portion 2 and hence, the thermal properties, i.e., heat removing properties, of the semiconductor device can be enhanced.

In manufacturing the semiconductor device 30, it is sufficient that the dicing lines 13 (see FIG. 17) which are arranged parallel to the long sides of the first major surface 1a of the metal plate 1 are made at positions overlapping with the metal plate 1 and thus a portion at the edge of the metal plate may be removed, and the dicing lines 13 which are arranged parallel to the short sides of the first major surface 1a of the metal plate 1 are made at positions outside the metal plate 1 (see FIG. 13). In an alternative embodiment, to miniaturize the semiconductor device 30 in the long-side direction of the first major surface 1a of the metal plate 1, the outer peripheral surfaces 1b, 1c may be exposed from the molded resin portion 2, and the outer peripheral surfaces 1d, 1e may be covered with the molded resin portion 2.

### Third Embodiment

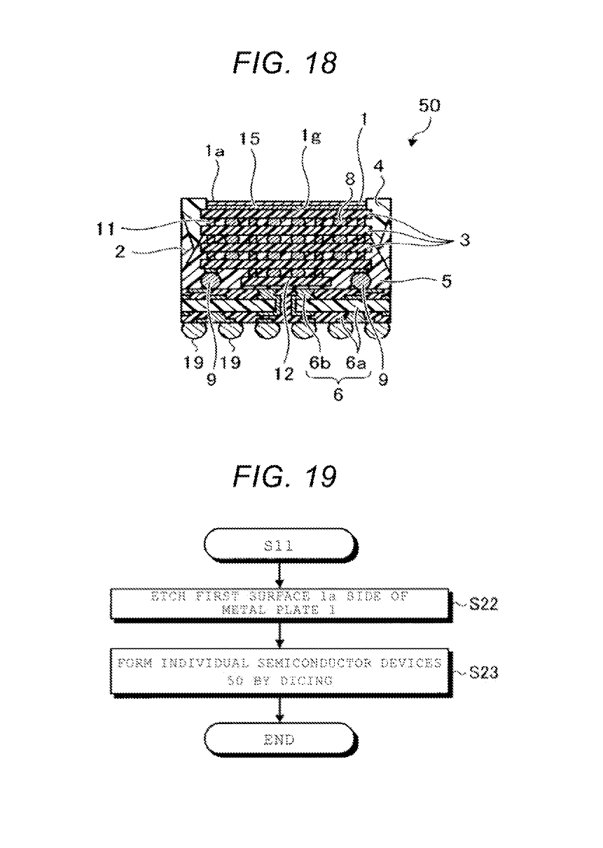

Next, a semiconductor device 50 according to a third embodiment is explained. FIG. 18 is a cross-sectional view of the semiconductor device 50 according to the third embodiment. In this embodiment, the same reference numerals for the elements of the above-mentioned embodiments are used in the description of the third embodiment and the detailed explanation of these elements are omitted for brevity.

In the semiconductor device 50, the sealing resin portion (first underfill resin 4) extends above the plane of the first major surface 1a of the metal plate 1. For example, in packaging the semiconductor device 50, a force or load applied to the semiconductor device 50 from a first major surface 1a side of the metal plate 1 can be received by a projecting portion of the sealing resin portion above the plane of the first major surface 1a and hence, it is possible to prevent the load from being applied directly to the metal plate 1. Due to such constitution, the metal plate 1 is difficult to remove or shift, and a load applied to the semiconductor memories 3, which are laminated on the metal plate 1, can be also suppressed and hence, the reliability of the semiconductor device can be enhanced.

In the same manner as the above-mentioned embodiments, the first major surface 1a of the metal plate 1 is exposed from the molded sealing resin portion and hence, the thermal properties of the semiconductor device may be enhanced. In this embodiment, the size of the metal plate 1 is smaller than the size of the semiconductor memory 3 as viewed in a plan view, whereas in the first two embodiments herein it is larger than the size of the semiconductor memory 3 as viewed in a plan view.

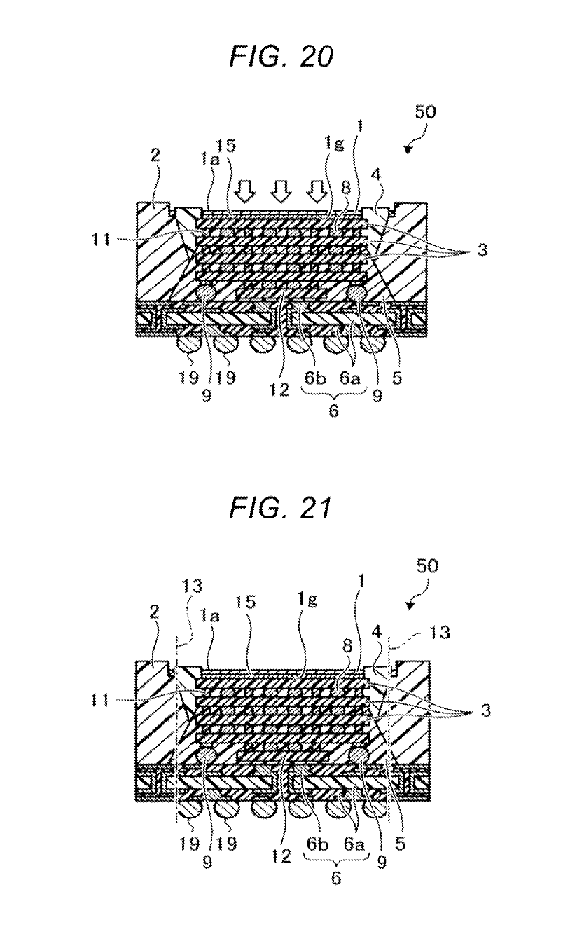

Next, a process of manufacturing the semiconductor device 50 is explained. FIG. 19 is a flowchart for explaining processes of manufacturing the semiconductor device 50 shown in FIG. 18. FIG. 20 to FIG. 21 are views showing a process of manufacturing the semiconductor device 50 shown in FIG. 18. According to this embodiment, the process is substantially the same as the corresponding process from up to the end of step 11 (step S1 to step S11) in the first embodiment shown in FIG. 4.

In this embodiment, the metal plate 1 is thinned after application of the molding resin to surround the sides 1b-1-e thereof. Thus, after step S11, a step of etching the first major surface 1a of the metal plate 1 is undertaken (see step S22 and FIG. 20). In this step, first major surface 1a of the metal plate 1 is etched by an amount greater than the thickness of the metal plate 1 at portions where the grooves if (See FIGS. 1-3) are formed on the second major surface 1g of the metal plate 1. As a result, the portion of the metal plate extending at the underside of the grooves if is completely removed.

Next, individual semiconductor devices 50 are formed by dicing (see step S23 and FIG. 21). In dicing, dicing lines 13 are made at positions overlapping with portions of the metal plate 1 where the grooves if were present prior to the etching step. Due to such a constitution, the sealing resin portion can project above the first major surface 1a of the metal plate 1. Further, by covering the peripheries of the outer peripheral surfaces 1b to 1e of the metal plate 1 with the sealing resin portion, the metal plate 1 is difficult to remove from the packaged device. Further, the dicing lines 13 overlap with the portions of the metal plate 1 where the grooves if were formed and hence, a sealing resin portion (resin molded portion 2) remains around the outer peripheral surfaces 1b to 1e of the metal plate 1. Accordingly, this embodiment may further miniaturize the semiconductor device 50 as viewed in a plan view compared with the case where the dicing lines 13 are made at the outside of the metal plate 1 which is not etched (see FIG. 1 and FIG. 14). Further, etching is applied to the metal plate 1 and hence, the reduction of a thickness of the semiconductor device 50 can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a metal plate including a first major surface having a quadrangular shape with four outer peripheral surfaces;
a plurality of semiconductor chips which are laminated on a second major surface of the metal plate opposite to the first major surface;
an insulation layer and a wiring layer disposed on the semiconductor chips;
a plurality of external connection terminals provided on the insulation layer and the wiring layer; and
a sealing resin which seals the plurality of semiconductor chips while exposing the first major surface of the metal plate, wherein
at least one pair of opposing outer peripheral surfaces of the metal plate are covered with the sealing resin.

2. The semiconductor device according to claim 1, wherein the metal plate and the insulation layer together from a cuboid portion having a cuboid shape; and
the plurality of external connection terminals are mounted on a surface of the cuboid portion, and

3. The semiconductor device according to claim 2, wherein
the first major surface of the metal plate has a rectangular shape having two opposing short sides and two opposing long sides,
the short sides of the metal plate are covered with the sealing resin, and
the long sides of the metal plate are not covered by the sealing resin.

4. The semiconductor device according to claim 3, wherein
portions of the sealing resin project above a plane of the first major surface of the metal plate.

5. The semiconductor device according to claim 2, wherein
the four outer peripheral surfaces are covered with the sealing resin.

6. The semiconductor device according to claim 1, wherein
the first major surface of the metal plate has a rectangular shape having two opposing short sides and two opposing long sides,
the short sides of the metal plate are covered with the sealing resin, and
the long sides of the metal plate are exposed.

7. The semiconductor device according to claim 6, wherein
portions of the sealing resin project above a plane of the first major surface of the metal plate.

8. The semiconductor device according to claim 1, wherein
four outer peripheral surfaces are covered with the sealing resin portion.

9. The semiconductor device according to claim 8, wherein the sealing resin portion extends above the metal plate.

10. The semiconductor device according to claim 1, wherein
the second major surface of the metal plate includes a groove formed therein.

11. A semiconductor device package comprising:
a metal plate including a first major surface having a quadrangular shape with four outer peripheral surfaces;
a plurality of semiconductor chips disposed on a second major surface of the metal plate opposite to the first major surface;
a circuit board electrically connected to the semiconductor chips;
a plurality of external connection terminals provided on the circuit board; and
a sealing resin surrounding the plurality of semiconductor chips and at least one pair of opposing outer peripheral surfaces of the metal plate while leaving the first major surface of the metal plate exposed.

12. The semiconductor device according to claim 11, wherein
the first major surface of the metal plate has a rectangular shape having two opposing short sides and two opposing long sides,
the short sides of the metal plate are covered with the sealing resin, and
the long sides of the metal plate are exposed.

13. The semiconductor device according to claim 12, wherein
portions of the sealing resin project above a plane of the first major surface of the metal plate.

14. The semiconductor device according to claim 11, wherein
the four outer peripheral surfaces are covered with the sealing resin.

15. The semiconductor device according to claim 11, wherein
the second major surface of the metal plate includes a groove formed therein.

16. A method of manufacturing a semiconductor device comprising:
forming a first laminated body by laminating a plurality of semiconductor chips on a first major surface of a metal plate having a quadrangular shape and including a second major surface opposing the first major surface;
forming a second laminated body by mounting a plurality of first laminated bodies on a support substrate;
disposing a mold about the second laminated body;
flowing a sealing resin in the mold to seal the plurality of semiconductor chips; and
dicing between the each of the first laminated bodies to form individual semiconductor devices, wherein
a dicing line used in the dicing is normal to the first major surface of the metal plate, and
the dicing line passes outside of the metal plate on at least two opposing outer peripheral sides of the metal plate.

17. The method according to claim 16, wherein
the mold includes a film disposed between the first major surface of the metal plate and a surface of the mold.

18. The method according to claim 16, wherein the first laminated body includes a first resin having a first viscosity and a second resin having a second viscosity that is different than the first viscosity.

19. The method according to claim 16, wherein
the metal plate includes four peripheral surfaces and the sealing resin covers all four peripheral surfaces.

20. The method according to claim 16, wherein
portions of the sealing resin project above a plane of the first major surface of the metal plate.
